(19) United States
(12) Patent Application Publication
(10) Pub. No.: US 2025/0197783 A1
(43) Pub. Date: Jun. 19, 2025

(54) PROCESSING SOLUTION, METHOD FOR PROCESSING SUBSTRATE, AND METHOD FOR MANUFACTURING SEMICONDUCTOR SUBSTRATE

(71) Applicant: TOKYO OHKA KOGYO CO., LTD., Kawasaki-shi (JP)

(72) Inventor: Shinya KOGA, Kawasaki-shi (JP)

(21) Appl. No.: 18/965,830

(22) Filed: Dec. 2, 2024

(30) Foreign Application Priority Data
Dec. 14, 2023 (JP) 2023-211054

(51) Int. Cl. C11D 7/50; C11D 7/32; H01L 21/02

(52) U.S. Cl. CPC C11D 7/5004; C11D 7/3209; H01L 21/02063; C11D 2111/22

(57) ABSTRACT

A processing solution for a semiconductor device, including a water-soluble organic solvent, water, and an ion of a typical metal element; a method for processing a substrate; and a method for manufacturing a semiconductor substrate.

### CROSS-REFERENCE TO RELATED APPLICATIONS

The present application claims priority to Japanese Patent Application No. 2023-211054, filed Dec. 14, 2023, the entire content of which is incorporated herein by reference.

### TECHNICAL FIELD

The present invention relates to a processing solution, a method for processing a substrate; and a method for manufacturing a semiconductor substrate.

### BACKGROUND ART

A semiconductor device is formed by laminating a metal wiring layer, a low dielectric layer, an insulating layer, etc. on a substrate such as a silicon wafer or the like. Such semiconductor device is manufactured by processing the above-mentioned layers by lithography, in which etching is performed with a resist pattern as a mask.

The resist pattern used in lithography and a filling (a temporarily laminated film, a sacrificial layer, a sacrificial film, a spin-on-glass (SOG) material, trench filling, etc.) as well as residues derived from the metal wiring layer and the low dielectric layer generated in etching process are removed with a cleaning solution so as not to impede the performance of the semiconductor device or to hinder the next process.

In recent years, as semiconductor devices become denser and more highly integrated, a wiring forming method using a damascene method has been employed. In the wiring forming method, copper, which is prone to corrosion, is employed as a metal wiring material constituting a metal wiring layer of a semiconductor device. Furthermore, as the dielectric constant of low dielectric materials (also called ILD materials) constituting a low dielectric layer becomes increasingly lower, corrosion-prone ILD materials have been widely employed. Therefore, there is a demand for the development of a cleaning solution that does not cause corrosion of these corrosion-prone materials when cleaning a substrate.

In the wiring forming method using a damascene method, materials that are used as a temporarily laminated film (sacrificial layer, sacrificial film, etc.) when etching is performed have very similar compositions to those of ILD materials. Hence, there is a demand to develop a cleaning solution that can leave one of these very similar materials (ILD material) on a device without causing corrosion to the ILD material while efficiently removing the other material (temporarily laminated film) from the device.

As a technology related to cleaning solutions for lithography used in such semiconductor device manufacturing process, Patent document 1 discloses a cleaning liquid used in a process for forming a dual damascene structure including steps of etching a low dielectric layer accumulated on a substrate having thereon a metallic layer to form a first etched-space; charging a sacrifice layer in the first etched-space; partially etching the low dielectric layer and the sacrifice layer to form a second etched-space connected to the first etched-space; and removing the sacrifice layer remaining in the first etched-space with the cleaning liquid, in which the cleaning liquid includes (a) 1-25 mass % of a quaternary ammonium hydroxide, (b) 30-70 mass % of a water soluble organic solvent, and (c) 20-60 mass % of water.

### Patent Document

Patent Document 1: Japanese patent application laid-open No. 2004-103771 (JP-A-2004-103771)

### SUMMARY OF THE INVENTION

For example, when etching is performed on a low dielectric layer with a resist pattern as a mask, the remaining resist pattern and an unnecessary layer and film to be removed need be removed using a processing solution after the etching process. However, a resist altered by etching and a layer and a film with high crosslinking density are difficult to remove, while a low-k material forming the low dielectric layer is prone to corrosion. For these reasons, there is a demand for effectively removing a filling while suppressing corrosion of a low-k material. However, in this regard, there is still room for improvement.

The present invention has been made in view of the above circumstances, and it is an object of the present invention to provide a processing solution, a method for processing a substrate, and a method for manufacturing a semiconductor substrate which are excellent in peelability of a filling and suppression of corrosion of a low-k material.

As a result of intensive studies to achieve the above object, the present inventor has found a processing solution for a semiconductor device, including: (a) a water-soluble organic solvent, (b) water, and (c) an ion of a typical metal element, and has thus completed the present invention.

That is, the present invention is as follows:
1) A processing solution for a semiconductor device, including: (a) a water-soluble organic solvent, (b) water, and (c) an ion of a typical metal element.
2) The processing solution according to 1, including as the ion of the typical metal element (c): at least one selected from the group consisting of (c-1) an ion of a Group 1 metal element, (c-2) an ion of a Group 2 metal element, and (c-3) an ion of a Group 13 metal element.
3) The processing solution according to 1, including as the ion of the typical metal element (c): (c-1) an ion of a Group 1 metal element, (c-2) an ion of a Group 2 metal element, and (c-3) an ion of a Group 13 metal element.
4) The processing solution according to 2, in which the ion of the Group 1 metal element (c-1) is a potassium ion and/or a sodium ion.
5) The processing solution according to 2, in which the ion of the Group 2 metal element (c-2) is a magnesium ion and/or a calcium ion.
6) The processing solution according to 2, in which the ion of the Group 13 metal element (c-3) is a boron ion and/or an aluminum ion.
7) The processing solution according to 2, in which the processing solution includes the ion of the Group 1 metal element (c-1) in an amount from 5×10⁴ ppb by mass to 1×10⁷ ppb by mass with respect to a total mass of the processing solution.
8) The processing solution according to 2, in which the processing solution includes the ion of the Group 2 metal element (c-2) in an amount from 1×10¹ ppb by mass to 1×10³ ppb by mass with respect to a total mass of the processing solution.
9) The processing solution according to 2, in which the processing solution includes the ion of the Group 13 metal element (c-3) in an amount from 1×10⁰ ppb by mass to 1×10² ppb by mass with respect to a total mass of the processing solution.
10) The processing solution according to 1, further including: (d) a base other than the component (a), the component (b), and the component (c).
11) The processing solution according to 10, in which the base (d) is a quaternary ammonium hydroxide compound.
12) A method for processing a substrate, including: a preparation step for obtaining a laminated substrate including a substrate, a low dielectric layer laminated on the substrate, and a resist pattern laminated on the substrate; and a processing step for processing the laminated substrate with the processing solution according to 1.
13) The method for processing the substrate according to 12, in which the preparation step is a step for obtaining a laminated substrate using a damascene method.
14) A method for manufacturing a semiconductor substrate, including: a preparation step for obtaining a laminated substrate comprising a substrate, a low dielectric layer laminated on the substrate, and a resist pattern laminated on the substrate; and a processing step for processing the laminated substrate with the processing solution according to 1.
15) The method for manufacturing the semiconductor substrate according to 14, further including: a step for forming metal wiring by embedding a metal in a pattern space of the resist pattern after the processing step.
16) The method for manufacturing the semiconductor substrate according to 14, in which the preparation step is a step for obtaining a laminated substrate using a damascene method.

According to the present invention, it is possible to provide a processing solution, a method for processing a substrate, and a method for manufacturing a semiconductor substrate which are excellent in peelability of a filling and suppression of corrosion of a low-k material.

### BRIEF DESCRIPTION OF THE DRAWINGS

### DETAILED DESCRIPTION OF THE INVENTION

Hereinafter, an embodiment for carrying out the present invention (hereinafter simply referred to as “the present embodiment”) will be described in detail. The present embodiment below is an example for explaining the present invention, and it is not intended to limit the present invention to the following description. The present invention may be implemented with any appropriate modification within the scope of its gist.

### Processing Solution

A processing solution according to the present embodiment is a processing solution for a semiconductor device, including: (a) a water-soluble organic solvent, (b) water, and (c) an ion of a typical metal element.

### (a) Water-Soluble Organic Solvent

The processing solution according to the present embodiment contains (a) a water-soluble organic solvent. Examples of the component (a) may include a highly polar solvent having a dipole moment of 3.0 D or more, a glycol ether-based solvent, polyhydric alcohols, etc.

As one specific example, the highly polar solvent may be one or more selected from the group consisting of sulfoxides such as dimethyl sulfoxide (DMSO) (dipole moment: 4.6 D), etc.; sulfones such as dimethyl sulfone (dipole moment: 5.1 D), diethyl sulfone (dipole moment: 4.7 D), tetramethylene sulfone (dipole moment: 5.0 D), etc.; amides such as N, N-dimethylformamide (DMF) (dipole moment: 4.5 D), N-methylformamide (dipole moment: 4.6 D), N, N-dimethylacetamide (DMAc) (dipole moment: 4.6 D), N-methylacetamide (dipole moment: 4.3 D), N, N-diethylacetamide (dipole moment: 4.7 D), etc.; lactams such as N-methyl-2-pyrrolidone (NMP) (dipole moment: 4.6 D), N-ethyl-2-pyrrolidone (dipole moment: 4.7 D), N-hydroxymethyl-2-pyrrolidone (dipole moment: 3.1 D), N-hydroxyethyl-2-pyrrolidone (dipole moment: 6.1 D), etc.; lactones such as β-propiolactone (dipole moment: 4.6 D), γ-butyrolactone (GBL) (dipole moment: 5.1 D), γ-valerolactone (dipole moment: 5.3 D), δ-valerolactone (dipole moment: 5.4 D), γ-caprolactone (dipole moment: 5.2 D), ε-caprolactone (dipole moment: 5.5 D), etc.; and imidazolidinones such as 1,3-dimethyl-2-imidazolidinone (DMI) (dipole moment: 4.5 D), 1,3-diethyl-2-imidazolidinone (dipole moment: 4.5 D), 1,3-diisopropyl-2-imidazolidinone (dipole moment: 4.3 D), etc.

Among these, a highly polar solvent having a dipole moment from 3.5 to 7.0 D is preferable, and a highly polar solvent having a dipole moment from 4.0 to 6.0 D is more preferable. In particular, from the viewpoint of stability in an alkaline chemical solution, the highly polar solvent is preferably one or more selected from the group consisting of sulfoxides, amides, lactams, and lactones, and more preferably one or more selected from the group consisting of dimethyl sulfoxide, N, N-dimethylformamide, N-methyl-2-pyrrolidone, and γ-butyrolactone.

Examples of the glycol ether-based solvent may include ethylene glycol monomethyl ether, ethylene glycol monoethyl ether, ethylene glycol monopropyl ether, ethylene glycol monobutyl ether, propylene glycol monomethyl ether (PGME), propylene glycol monoethyl ether, propylene glycol monopropyl ether, propylene glycol monobutyl ether, diethylene glycol monomethyl ether (MDG), diethylene glycol monoethyl ether (EDG), diethylene glycol monopropyl ether, diethylene glycol monobutyl ether (BDG), etc.

Among these, from the viewpoints of water solubility, resist pattern removal performance, flammability, etc., the glycol ether-based solvent is preferably at least one selected from the group consisting of diethylene glycol monomethyl ether (MDG), diethylene glycol monoethyl ether (EDG), diethylene glycol monopropyl ether, and diethylene glycol monobutyl ether (BDG), and more preferably at least one selected from the group consisting of diethylene glycol monomethyl ether (MDG), diethylene glycol monoethyl ether (EDG), and diethylene glycol monobutyl ether (BDG).

Examples of the polyhydric alcohol may include ethylene glycol, propylene glycol, butylene glycol, glycerin, etc. Among these, from the viewpoints of safety, viscosity, etc., the polyhydric alcohol is preferably at least one selected from the group consisting of ethylene glycol, propylene glycol, and glycerin.

As the water-soluble organic solvent (a), the above-mentioned substances may be used alone or in combination of two or more. For example, the combination may preferably contain two or more selected from the group consisting of the highly polar solvent having a dipole moment of 3.0 D or more, the glycol ether-based solvent, and the alcohols. For example, the combination may more preferably contain the highly polar solvent having a dipole moment of 3.0 D or more, the glycol ether-based solvent, and the polyhydric alcohols. For example, the combination may even more preferably contain: as the highly polar solvent, one or more selected from the group consisting of sulfoxides, amides, lactams, and lactones; as the glycol ether-based solvent, at least one selected from the group consisting of diethylene glycol monomethyl ether (MDG), diethylene glycol monoethyl ether (EDG), and diethylene glycol monobutyl ether (BDG); and as the polyhydric alcohols, at least one selected from the group consisting of ethylene glycol, propylene glycol, and glycerin. For example, the combination may still even more preferably contain: as the highly polar solvent, one or more selected from the group consisting of dimethyl sulfoxide, N,N-dimethylformamide, N-methyl-2-pyrrolidone, and γ-butyrolactone; as the glycol ether-based solvent, at least one selected from the group consisting of diethylene glycol monomethyl ether (MDG), diethylene glycol monoethyl ether (EDG), and diethylene glycol monobutyl ether (BDG); and as the polyhydric alcohols, at least one selected from the group consisting of ethylene glycol, propylene glycol, and glycerin.

The content of the water-soluble organic solvent (a) is preferably from 15 to 80% by mass with respect to the total amount of the processing solution. The lower limit thereof is more preferably 20% by mass or more, and even more preferably 25% by mass or more. The upper limit thereof is more preferably 70% by mass or less, and even more preferably 60% by mass or less.

When the highly polar solvent is contained, the content of the highly polar solvent is preferably from 5 to 60% by mass with respect to the total amount of the processing solution. The lower limit thereof is more preferably 10% by mass or more, and even more preferably 20% by mass or more. The upper limit thereof is more preferably 50% by mass or less, and even more preferably 30% by mass or less. By setting the content of the highly polar solvent to the above range, effects of peelability of a filling and suppression of corrosion of a low-k material can be further improved.

When the glycol ether-based solvent is contained, the content of the glycol ether-based solvent is preferably from 5 to 55% by mass with respect to the total amount of the processing solution. The lower limit thereof is more preferably 10% by mass or more, and even more preferably 15% by mass or more. The upper limit thereof is more preferably 30% by mass or less, and even more preferably 20% by mass or less. By setting the content of the glycol ether-based solvent to the above range, effects of peelability of a filling and suppression of corrosion of a low-k material can be further improved.

When the polyhydric alcohol is contained, the content of the polyhydric alcohol is preferably from 5 to 30% by mass with respect to the total amount of the processing solution. The lower limit thereof is more preferably 10% by mass or more, and even more preferably 15% by mass or more. The upper limit thereof is more preferably 25% by mass or less. By setting the content of the polyhydric alcohol to the above range, effects of peelability of a filling and suppression of corrosion of a low-k material can be further improved.

### (b) Water

The processing solution according to the present embodiment contains (b) water. The content of the water (b) may be the remaining part of the processing solution other than the components except for water. The content of the water (b) is preferably from 15% by mass to 85% by mass with respect to the total amount of the processing solution. The lower limit thereof may be 20% by mass or more, may be 25% by mass or more, or may be a value greater than 40% by mass. The upper limit thereof may be less than 80% by mass, less than 75% by mass, less than 65% by mass, or less than 60% by mass. By setting the water content to the above range, effects of peelability of a filling and suppression of corrosion of a low-k material can be further improved.

### (c) Ion of Typical Metal Element

The processing solution according to the present embodiment contains (c) an ion of a typical metal element. As the component (c), the processing solution according to the present embodiment preferably contains at least one metal ion selected from the group consisting of an ion of a Group 1 metal element (c-1), an ion of a Group 2 metal element (c-2), and an ion of a Group 13 metal element (c-3).

Examples of the ion of the Group 1 metal element (c-1) may include a lithium (Li) ion, a sodium (Na) ion, a potassium (K) ion, a rubidium (Rb) ion, a cesium (Cs) ion, etc. Among these, a potassium ion and a sodium ion are preferable. The processing solution according to the present embodiment more preferably contains a potassium ion and/or a sodium ion.

Examples of the ion of the Group 2 metal element (c-2) may include a beryllium (Be) ion, a magnesium (Mg) ion, a calcium (Ca) ion, a strontium (Sr) ion, a barium (Ba) ion, etc. Among these, a magnesium ion and a calcium ion are preferable. The processing solution according to the present embodiment more preferably contains a magnesium ion and/or a calcium ion.

Examples of the ion of the Group 13 metal element (c-3) may include a boron (B) ion, an aluminum (Al) ion, a gallium (Ga) ion, an indium (In) ion, etc. Among these, a boron ion and an aluminum ion are preferable. The processing solution according to the present embodiment more preferably contains a boron ion and/or an aluminum ion.

When the ion of the Group 1 metal element (c-1) is contained as the component (c), the content of the ion of the Group 1 metal element (c-1) with respect to the total mass of the processing solution is preferably from 5× 10⁴ ppb by mass to 1×10⁷ ppb by mass. The lower limit thereof is preferably 1×10⁵ ppb by mass or more, more preferably 3×10⁵ ppb by mass or more, and even more preferably 4×10⁵ ppb by mass or more. The upper limit thereof is more preferably 1×10⁶ ppb by mass or less, even more preferably 9× 10⁵ ppb by mass or less, and still even more preferably 8×10⁵ ppb by mass or less. When two or more kinds of ions are contained as the component (c-1), the total amount of the component (c-1) is preferably in the above range.

When the ion of the Group 2 metal element (c-2) is contained as the component (c), the content of the ion of the Group 2 metal element (c-2) with respect to the total mass of the processing solution is preferably from 1×10¹ ppb by mass to 1× 10³ ppb by mass. The lower limit thereof is more preferably 5×10¹ ppb by mass or more, even more preferably 1×10² ppb by mass or more, and still even more preferably 1.5×10² ppb by mass or more. The upper limit thereof is more preferably 7×10² ppb by mass or less, even more preferably 6×10² ppb by mass or less, and still even more preferably 5× 10² ppb by mass or less. When two or more kinds of ions are contained as the component (c-2), the total amount of the component (c-2) is preferably in the above range.

When the ion of the Group 13 metal element (c-3) is contained as the component (c), the content of the ion of the Group 13 metal element (c-3) with respect to the total mass of the processing solution is preferably from 1× 10⁰ ppb by mass to 1×10² ppb by mass. The lower limit thereof is more preferably 5×10⁰ ppb by mass or more, more preferably 1×10¹ ppb by mass or more, and even more preferably 1.5×10¹ ppb by mass or more. The upper limit thereof is more preferably 9×10¹ ppb by mass or less, more preferably 7×10¹ ppb by mass or less, even more preferably 6×10¹ ppb by mass or less, and still even more preferably 5×10¹ ppb by mass or less. When two or more kinds of ions are contained as the component (c-3), the total amount of the component (c-3) is preferably in the above range.

### (d) Base

The processing solution according to the present embodiment preferably further contains (d) a base. The base (d) is a base other than the component (a), the component (b), and the component (c). Examples of the base (d) may include quaternary ammonium hydroxide compounds such as tetramethylammonium hydroxide (TMAH), tetraethylammonium hydroxide (TEAH), etc.; and the like. Among these, a quaternary ammonium hydroxide compound is preferable, and tetramethylammonium hydroxide (TMAH) and tetraethylammonium hydroxide (TEAH) are more preferable.

When the base (d) is contained, the content of the base (d) is preferably from 0.5% by mass to 20% by mass with respect to the total amount of the processing solution. The lower limit thereof is more preferably 2% by mass or more, and even more preferably 4% by mass or more. The upper limit thereof is more preferably 18% by mass or less, and even more preferably 15% by mass or less. By setting the content of the base (d) to the above range, effects of peelability of a filling and suppression of corrosion of a low-k material can be further improved. When two or more kinds of bases are contained as the base (d), the total amount of the base (d) is preferably in the above range.

### (e) Anticorrosive Agent

The processing solution according to the present embodiment may further contain (e) an anticorrosive agent. The processing solution according to the present embodiment can be expected to also have an anticorrosion effect by the anticorrosive agent (e). The anticorrosive agent (e) may be preferably at least one selected from the group consisting of a benzotriazole-based compound, and a mercapto group-containing compound.

Examples of the benzotriazole-based compound may include a compound represented by the following general formula (1).

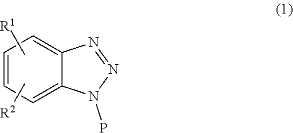

In the general formula (1), R¹ and R² each independently represents a hydrogen atom, a hydrocarbon group having 1 to 10 carbon atoms that may have a substituent, a carboxyl group, an amino group, a hydroxyl group, a cyano group, a formyl group, a sulfonylalkyl group, or a sulfo group; P represents a hydrogen atom, a hydroxyl group, a hydrocarbon group having 1 to 14 carbon atoms that may have a substituent (Note that this hydrocarbon group may be interrupted by an amide bond or an ester bond.), or a group represented by the following general formula (2).

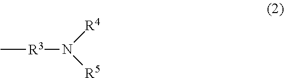

In the general formula (2), R³ represents an alkylene group having 1 to 6 carbon atoms, and R⁴ and R⁵ each independently represents a hydrogen atom, a hydroxyl group, or a hydroxyalkyl or alkoxyalkyl group having 1 to 6 carbon atoms.

In the definitions of R¹, R², and P in the general formula (1), the hydrocarbon group may be either an aromatic hydrocarbon group or an aliphatic hydrocarbon group, may have an unsaturated bond, and may be linear, branched, or cyclic. Examples of the aromatic hydrocarbon group may include a phenyl group, a p-tolyl group, etc. Examples of the linear aliphatic hydrocarbon group may include a methyl group, an n-propyl group, a vinyl group, etc. Examples of the branched aliphatic hydrocarbon group may include an isobutyl group, a tert-butyl group, etc. Examples of the cyclic aliphatic hydrocarbon group may include a cyclopentyl group, a cyclohexyl group, etc. Examples of the hydrocarbon group having a substituent may include a hydroxyalkyl group, an alkoxyalkyl group, etc.

In the general formula (1), P is preferably a group represented by the general formula (2). In particular, among the groups represented by the general formula (2), it is preferable that R⁴ and R⁵ be a hydroxyalkyl or alkoxyalkyl group having 1 to 6 carbon atoms, which are selected independently of each other.

Furthermore, P is preferably selected so that the compound represented by the general formula (1) exhibits water solubility. Specifically, a hydrogen atom, an alkyl group having 1 to 3 carbon atoms (that is, a methyl group, an ethyl group, a propyl group, an isopropyl group), a hydroxyalkyl group having 1 to 3 carbon atoms, a hydroxyl group, etc. are preferable.

Examples of the benzotriazole-based compound may include benzotriazole, 5,6-dimethylbenzotriazole, 1-hydroxybenzotriazole, 1-methylbenzotriazole, 1-aminobenzotriazole, 1-phenylbenzotriazole, 1-hydroxymethylbenzotriazole, methyl 1H-benzotriazolecarboxylate, 5-benzotriazolecarboxylic acid, 1-methoxy-benzotriazole, 1-(2,2-dihydroxyethyl)-benzotriazole, 1-(2,3-dihydroxypropyl)benzotriazole, 2,2′-{[(4-methyl-1H-benzotriazol-1-yl)methyl]imino}bisethanol, 2,2′-{[(5-methyl-1H-benzotriazol-1-yl)methyl]imino}bisethanol, 2,2′-{[(4-methyl-1H-benzotriazol-1-yl)methyl]imino}bisethane, 2,2′-{[(4-methyl-1H-benzotriazol-1-yl)methyl]imino}bispropane, etc. Among these, 1-(2,3-dihydroxypropyl)-benzotriazole, 2,2′-{[(4-methyl-1H-benzotriazol-1-yl)methyl]imino}bisethanol, 2,2′-{[(5-methyl-1H-benzotriazol-1-yl)methyl]imino}bisethanol, etc. are preferably used. These may be used alone or in combination of two or more.

The mercapto group-containing compound may be preferably a compound having a hydroxyl group and/or a carboxyl group on an α-position carbon atom and/or a β-position carbon atom bonded to a mercapto group. Examples of the compound may include 1-thioglycerol, 3-(2-aminophenylthio)-2-hydroxypropyl mercaptan, 3-(2-hydroxyethylthio)-2-hydroxypropyl mercaptan, 2-mercaptopropionic acid, 3-mercaptopropionic acid, etc. Among these, 1-thioglycerol is preferable. These may be used alone or in combination of two or more.

### Surfactant

The processing solution according to the present embodiment may include a surfactant, as necessary. As the surfactant, an acetylene alcohol-based surfactant or the like can be preferably used. The content of the surfactant is preferably less than 0.5% by mass with respect to the total amount of the processing solution.

### Processing Method, Semiconductor Substrate Manufacturing Method, Wiring Forming Method, Etc.

The processing solution according to the present embodiment is a processing solution for lithography, but can be suitably used for processing an etched laminated substrate. One example may be a method for processing a substrate, including: a preparation step for obtaining a laminated substrate including a substrate, a low dielectric layer laminated on the substrate, and a resist pattern laminated on the substrate; and a processing step for processing the laminated substrate with the processing solution described above.

The preparation step for obtaining a laminated substrate described above may include: a step for preparing a laminated substrate including a substrate, a low dielectric layer formed on a surface of the substrate, and a resist pattern formed on a surface of the substrate (pre-processing step); and a step for forming an etching space in the resist pattern of the laminated substrate by an etching process (etching step).

The preparation step for obtaining a laminated substrate preferably uses a damascene method to obtain a laminated substrate. That is, the preparation step described above is preferably a step in which a laminated substrate is obtained using a damascene method.

The laminated substrate to be processed may have any layer structure as long as it includes a substrate, a low dielectric layer, and a resist pattern layer, or the laminated substrate to be processed may have a multilayer structure further including another layer. For example, various layers described later may be provided between the substrate and the low dielectric layer or between the low dielectric layer and the resist pattern layer, or an additional layer may be provided on the resist pattern layer.

The processing solution and the processing method according to the present embodiment can be suitably used for a method for processing a semiconductor substrate. For example, they can be suitably used for a method for processing a semiconductor substrate when an etched laminated substrate is processed. One preferred example of the method for manufacturing the semiconductor substrate may be a method for manufacturing a semiconductor substrate that includes a preparation step for obtaining a laminated substrate including a substrate, a low dielectric layer laminated on the substrate, and a resist pattern laminated on the substrate; and a processing step for processing the laminated substrate with the processing solution described above.

Furthermore, the method for manufacturing the semiconductor substrate preferably includes a step for forming metal wiring by embedding a metal in a pattern space of the resist pattern after the processing step. By performing such a step, fine metal wiring can be formed in a space such as a via hole, a trench, etc., and a semiconductor substrate having a damascene structure described later can be obtained.

The preparation step for obtaining a laminated substrate preferably uses a damascene method to obtain a laminated substrate. That is, the preparation step described above is preferably a step in which a laminated substrate is obtained by using a damascene method.

As described above, the processing solution according to the present embodiment is a processing solution for lithography, but can be suitably used particularly in a wiring forming method using a damascene method. More specifically, the processing solution according to the present embodiment can be used for a wiring forming method using a damascene method, in which a metal wiring layer is formed by embedding a metal in a pattern space (etching space, etc.) formed in a low dielectric layer with a resist pattern. The processing solution according to the present embodiment can be suitably used in either a single damascene process or a dual damascene process. Hereinafter, some aspects will be illustratively described.

One example of the wiring forming method using a damascene method may be a method in which a resist pattern (e.g. a trench resist pattern) is formed as a mask on a low dielectric layer formed on a substrate, the low dielectric layer is etched to form an etching space (trench pattern, groove), and metal wiring is formed by embedding a metal in the etching space. Incidentally, a bottom anti-reflective coating (BARC) or the like may be formed under the resist pattern. The etching space may be temporarily filled with a sacrificial film.

As a more specific example, the case of a semiconductor substrate with Cu metal wiring in a dual damascene structure will be described. In the case of Cu metal wiring, a method of forming Cu multilayer wiring using a damascene method can be preferably used since the etching resistance of Cu is low. Various methods have been proposed as the dual damascene method, and one example is given here. After a Cu layer is provided on a substrate, a low dielectric layer is laminated thereon. After that, a photoresist pattern is formed on the topmost layer by lithography technology. Using the photoresist pattern as a mask, the low dielectric layer is etched to form a via hole that communicates with the Cu layer. Then, the photoresist pattern is peeled off. Subsequently, the via hole is filled with a sacrificial layer of an alkoxysilane material or the like. Next, a new photoresist pattern is formed on the topmost layer of the remaining multilayer laminate, and using this as a mask, the low dielectric layer and the sacrificial layer are etched to form a groove (trench) for wiring that communicates with the via hole. After that, the sacrificial layer remaining in the via hole is cleaned and removed. Then, after peeling off the photoresist pattern, the via hole and the trench are filled with Cu by plating or the like, thereby forming multilayer Cu wiring.

The processing solution according to the present embodiment can effectively remove a resist pattern after etching and residues derived from a low dielectric layer and a metal wiring layer generated in an etching step. Since the processing solution according to the present embodiment is excellent in peelability of a filling and in suppression of corrosion of a low-k material, it is possible to effectively remove a resist pattern, a bottom anti-reflective coating, etc. while suppressing corrosion of an ILD material. Therefore, after an etching space is formed in a low dielectric layer by using a resist pattern and a bottom anti-reflective coating, the processing solution according to the present embodiment can also be suitably used at least in removing the resist pattern and the bottom anti-reflective coating.

A method for removing the resist pattern and the residues using the processing solution according to the present embodiment is not particularly limited as long as it is a commonly used removal method. Specifically, the removal processing is performed by bringing the processing solution according to the present embodiment into contact with the substrate using, for example, a dipping method, a paddle method, a shower method, or the like. The immersion time is, for example, from 5 seconds to 60 minutes, although not particularly limited, and the immersion temperature is, for example, from 20 to 80° C., although not particularly limited.

As a material for forming the resist pattern, a resist material commonly used for excimer lasers (KrF, ArF, F2, EUV) or electron beams can be used in a conventional manner. As a material for forming the bottom anti-reflective coating, a commonly used inorganic or organic bottom anti-reflective coating material can be used in a conventional manner.

Using such resist material or bottom anti-reflective coating material, a resist pattern or a bottom anti-reflective coating is formed on an interlayer insulating layer or on a barrier layer above the interlayer insulating layer. After pattern exposure via a mask, a resist pattern is formed by a development process. Next, a resist pattern residue after etching is performed using the resist pattern as a mask, as well as a residue derived from the bottom anti-reflective coating, a residue derived from a sacrificial film, and a residue derived from a metal wiring layer or a low dielectric layer generated during the etching process, are removed by the processing solution according to the present embodiment.

Specifically, the low dielectric layer such as the above-mentioned low-k film, etc. is, for example, a layer formed of a carbon-doped oxide (SiOC)-based, methyl silsesquioxane (MSQ)-based, or hydroxysilsesquioxane (HSQ)-based material. The low dielectric layer preferably has a dielectric constant (k) of 3.0 or less so as not to affect the electrical characteristics of a metal wiring layer.

Examples of the barrier layer may include SiC, SiN, SiCN, Ta, TaN, etc. Such barrier layer may be formed between low dielectric layers.

A metal material forming the metal wiring layer used in a damascene method is mainly Cu, but conductive materials other than Cu such as Al, Ti, W, etc. are also laminated on the same substrate. According to the processing solution of the present embodiment, even if the processing solution comes into contact with these metal materials, corrosion can be effectively suppressed.

Among damascene methods, the processing solution according to the present embodiment is particularly useful in a wiring forming method employing a damascene method in which a sacrificial film is temporarily provided in an etching space formed. Specifically, a spin-on-glass (SOG) material obtained by a condensation reaction is suitable as a material (filling) for forming the sacrificial film. Incidentally, the spin-on glass material can also be used to reduce steps of interlayer insulating films, to fill in a trench between wires, etc.

As the spin-on glass material for forming the sacrificial film, a material described in JP-A-2001-092122 can be used, for example. As a specific example of the spin-on glass material, a compound obtained by hydrolyzing at least one selected from compounds represented by the following general formulae (3) to (5) by an action of an acid in the presence of water is suitable. From this viewpoint, a more suitable spin-on-glass material is a compound obtained by hydrolyzing a combination of a compound represented by the following general formula (3) and a compound represented by the following general formula (4) by an action of an acid in the presence of water.

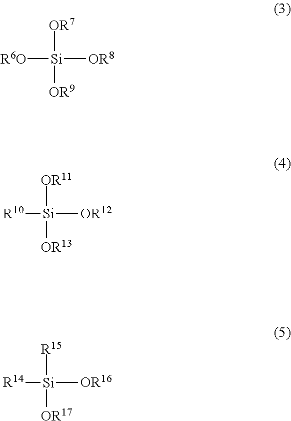

In the general formulae (3) to (5), R⁶ to R⁹, R¹¹ to R¹³, R¹⁶, and R¹⁷ each independently represents an alkyl or phenyl group having 1 to 4 carbon atoms, and R¹⁰, R¹⁴ and R¹⁵ each independently represents a hydrogen atom or an alkyl group having 1 to 4 carbon atoms.

Among compounds represented by the general formula (3), tetramethoxysilane or tetraethoxysilane, or oligomers thereof are preferable. Among compounds represented by the general formula (4), tetramethoxysilane or tetraethoxysilane, or oligomers thereof are preferable. Furthermore, among compounds represented by the general formula (5), dimethoxysilane, diethoxysilane, or methyldimethoxysilane, or oligomers thereof are preferable. One or two or more kinds of these spin-on glass materials can be appropriately selected and used.

Furthermore, a highly absorbent material may be appropriately blended in the compounds represented by the general formulae (3) to (5). The highly absorbent material is not particularly limited as long as: it has a substituent in its structure that can be condensed with the above spin-on glass material; and it has a high absorption ability for light in the wavelength region where a photosensitive component in the above resist material has sensitivity to light to prevent standing waves caused by reflected light from the substrate and diffused reflection caused by steps on the substrate surface. Examples thereof may include a sulfone-based compound that may have a hydroxyl group and/or a carboxyl group, a benzophenone-based compound that may have a hydroxyl group and/or a carboxyl group, an anthracene-based compound that may have a hydroxyl group and/or a carboxyl group, a naphthalene-based compound that may have a hydroxyl group and/or a carboxyl group, etc. In particular, a bisphenylsulfone-based compound and a benzophenone-based compound that have at least two hydroxyl groups, an anthracene-based compound having at least one hydroxyl group and/or at least one hydroxyalkyl group, an anthracene-based compound having a carboxyl group and/or a hydroxyl group, and a naphthalene-based compound having at least one carboxyl group and/or at least one hydroxyl group are preferable.

The content of the highly absorbent material in the spin-on glass material is preferably from 10 to 50% by mass, more preferably from 15 to 40% by mass in terms of solid content concentration in terms of SiO₂.

### EXAMPLES

The present invention will be described in more detail with reference to the following Examples and Comparative examples, but the present invention is not limited in any way to the following examples. The experiments were conducted at 25° C. and atmospheric pressure unless otherwise specified.

### Preparation of Processing Solution for Lithography

Processing solutions for lithography were prepared based on the compositions and amounts given in Tables 1 to 4. The reagents were commercially available reagents unless otherwise specified. In addition, the numerical values in the tables are expressed in the unit of mass % unless otherwise specified.

The abbreviations in the tables are as follows.
TMAH: Tetramethylammonium hydroxide
TEAH: Tetraethylammonium hydroxide
DMSO: Dimethyl sulfoxide
NMP: N-Methyl-2-pyrrolidone
DMF: N,N-Dimethylformamide
GBL: γ-Butyrolactone
EDG: Diethylene glycol monoethyl ether
MDG: Diethylene glycol monomethyl ether
BDG: Diethylene glycol monobutyl ether
PG: Propylene glycol
EG: Ethylene glycol

For example, the processing solution for lithography in Example 1 contains: as the water-soluble organic solvent (a), 5% by mass of dimethyl sulfoxide (DMSO), 35% by mass of diethylene glycol monoethyl ether (EDG), and 20% by mass of propylene glycol (PG); as the ion of the Group 1 metal element (c-1), 2×10² ppb by mass of Na ions and 5×10⁵ ppb by mass of K ions; as the ion of Group 2 metal element (c-2), 2×10² ppb by mass of Mg ions, and 5×10⁻¹ ppb by mass of Ca ions; as the ion of Group 13 metal element (c-3), 2× 10¹ ppb by mass of B ions, and 4×10⁻¹ ppb by mass of Al ions; as the base (d), 10% by mass of tetramethylammonium hydroxide (TMAH); and water (b) as the balance.

TABLE 1

| | (a) | | | | | |
|---|---|---|---|---|---|---|
| | Water-soluble | | | | (c-1) | |
| | organic solvent | | | (b) | Group 1 metal ion | |
| | (mass %) | | | Water | (mass %) | |
| Example | DMSO | EDG | PG | (Balance) | Na | K |
| 1 | (5) | (35) | (20) | | (2 × 10²ppb) | (5 × 10²ppb) |
| Example | DMSO | EDG | PG | (Balance) | Na | K |
| 2 | (10) | (55) | (5) | | (2 × 10²ppb) | (5 × 10²ppb) |
| Example | DMSO | MDG | Glycerin | (Balance) | Na | K |
| 3 | (40) | (10) | (10) | | (2 × 10²ppb) | (5 × 10²ppb) |
| Example | DMF | EDG | PG | (Balance) | Na | K |
| 4 | (40) | (20) | (10) | | (2 × 10²ppb) | (5 × 10²ppb) |
| Example | DMSO | BDG | PG | (Balance) | Na | K |
| 5 | (20)x | (20) | (20) | | (2 × 10²ppb) | (5 × 10²ppb) |
| Example | NMP | EDG | PG | (Balance) | Na | K |
| 6 | (40) | (20) | (10) | | (2 × 10²ppb) | (5 × 10²ppb) |
| Example | DMSO | BDG | PG | (Balance) | Na | K |
| 7 | (60) | (10) | (10) | | (2 × 10²ppb) | (5 × 10²ppb) |
| Example | NMP | EDG | EG | (Balance) | Na | K |
| 8 | (30) | (20) | (10) | | (2 × 10²ppb) | (5 × 10²ppb) |
| Example | DMF | BDG | PG | (Balance) | Na | K |
| 9 | (22.5) | (22.5) | (15) | | (2 × 10²ppb) | (5 × 10²ppb) |
| Example | DMSO | BDG | PG | (Balance) | Na | K |
| 10 | (17.5) | (17.5) | (25) | | (2 × 10²ppb) | (5 × 10²ppb) |
| Example | GBL | BDG | PG | (Balance) | Na | K |
| 11 | (17.5) | (17.5) | (25) | | (2 × 10²ppb) | (5 × 10²ppb) |

| | | |
|---|---|---|
| (c-2) | (c-3) | (d) |
| Group 2 metal ion | Group 13 metal ion | Base |
| (mass %) | (mass %) | (mass %) |

| | | | | | |
|---|---|---|---|---|---|
| Example | Mg | Ca | B | Al | TMAH |
| 1 | (2 × 10²ppb) | (5 × 10⁻¹ppb) | (2 × 10¹ppb) | (4 × 10⁻¹ppb) | (10) |
| Example | Mg | Ca | B | Al | TMAH |
| 2 | (2 × 10²ppb) | (5 × 10⁻¹ppb) | (2 × 10¹ppb) | (4 × 10⁻¹ppb) | (7.5) |
| Example | Mg | Ca | B | Al | TMAH |
| 3 | (2 × 10²ppb) | (5 × 10⁻¹ppb) | (2 × 10¹ppb) | (4 × 10⁻¹ppb) | (10) |
| Example | Mg | Ca | B | Al | TMAH |
| 4 | (2 × 10²ppb) | (5 × 10⁻¹ppb) | (2 × 10¹ppb) | (4 × 10⁻¹ppb) | (7.5) |
| Example | Mg | Ca | B | Al | TEAH |
| 5 | (2 × 10²ppb) | (5 × 10⁻¹ppb) | (2 × 10¹ppb) | (4 × 10⁻¹ppb) | (10) |
| Example | Mg | Ca | B | Al | TMAH |
| 6 | (2 × 10²ppb) | (5 × 10⁻¹ppb) | (2 × 10¹ppb) | (4 × 10⁻¹ppb) | (7.5) |
| Example | Mg | Ca | B | Al | TMAH |
| 7 | (2 × 10²ppb) | (5 × 10⁻¹ppb) | (2 × 10¹ppb) | (4 × 10⁻¹ppb) | (5) |
| Example | Mg | Ca | B | Al | TMAH |
| 8 | (2 × 10²ppb) | (5 × 10⁻¹ppb) | (2 × 10¹ppb) | (4 × 10⁻¹ppb) | (7.5) |
| Example | Mg | Ca | B | Al | TMAH |
| 9 | (2 × 10²ppb) | (5 × 10⁻¹ppb) | (2 × 10¹ppb) | (4 × 10⁻¹ppb) | (10) |
| Example | Mg | Ca | B | Al | TMAH |
| 10 | (2 × 10²ppb) | (5 × 10⁻¹ppb) | (2 × 10¹ppb) | (4 × 10⁻¹ppb) | (10) |
| Example | Mg | Ca | B | Al | TMAH |
| 11 | (2 × 10²ppb) | (5 × 10⁻¹ppb) | (2 × 10¹ppb) | (4 × 10⁻¹ppb) | (10) |

TABLE 2

| | (a) | | | | | | | | | | |
|---|---|---|---|---|---|---|---|---|---|---|---|
| | Water-soluble | | | | (c-1) | | (c-2) | | (c-3) | | (d) |
| | organic solvent | | | (b) | Group 1 metal ion | | Group 2 metal ion | | Group 13 metal ion | | Base |
| | (mass %) | | | Water | (mass %) | | (mass %) | | (mass %) | | (mass %) |
| Example | DMSO | EDG | PG | (Balance) | Na | K | Mg | Ca | B | Al | TMAH |
| 12 | (10) | (20) | (30) | | (2 × 10²ppb) | (5 × 10⁵ppb) | (2 × 10²ppb) | (5 × 10⁻¹ppb) | (2 × 10¹ppb) | (4 × 10⁻¹ppb) | (10) |
| Example | DMSO | EDG | PG | (Balance) | Na | K | Mg | Ca | B | Al | TMAH |
| 13 | (50) | (5) | (5) | | (2 × 10²ppb) | (5 × 10⁵ppb) | (2 × 10²ppb) | (5 × 10⁻¹ppb) | (2 × 10¹ppb) | (4 × 10⁻¹ppb) | (7.5) |
| Example | DMSO | EDG | PG | (Balance) | Na | K | Mg | Ca | B | Al | TMAH |
| 14 | (5) | (35) | (20) | | (1 × 10²ppb) | (5 × 10⁵ppb) | (7 × 10¹ppb) | (1 × 10⁰ppb) | (1 × 10¹ppb) | (3 × 10⁻¹ppb) | (10) |
| Example | DMSO | EDG | PG | (Balance) | Na | K | Mg | Ca | B | Al | TMAH |
| 15 | (5) | (35) | (20) | | (5 × 10¹ppb) | (1 × 10⁵ppb) | (3 × 10¹ppb) | (5 × 10⁻¹ppb) | (5 × 10⁰ppb) | (1 × 10⁻¹ppb) | (10) |
| Example | DMSO | EDG | — | (Balance) | Na | K | Mg | Ca | B | Al | TMAH |
| 16 | (30)x | (30) | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | DMSO | EDG | — | (Balance) | Na | K | Mg | Ca | B | Al | TMAH |
| 17 | (20) | (20) | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | DMSO | EDG | — | (Balance) | Na | K | Mg | Ca | B | Al | TMAH |
| 18 | (10) | (10) | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | DMSO | BDG | — | (Balance) | Na | K | Mg | Ca | B | Al | TMAH |
| 19 | (30) | (30) | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | DMSO | BDG | — | (Balance) | Na | K | Mg | Ca | B | Al | TMAH |
| 20 | (20) | (20) | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | DMSO | BDG | — | (Balance) | Na | K | Mg | Ca | B | Al | TMAH |
| 21 | (10) | (10) | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | DMSO | — | — | (Balance) | Na | K | Mg | Ca | B | Al | TMAH |
| 22 | (60) | | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |

TABLE 3

| | (a) | | | | | | | | | | |
|---|---|---|---|---|---|---|---|---|---|---|---|
| | Water-soluble | | | | (c-1) | | (c-2) | | (c-3) | | (d) |
| | organic solvent | | | (b) | Group 1 metal ion | | Group 2 metal ion | | Group 13 metal ion | | Base |
| | (mass %) | | | Water | (mass %) | | (mass %) | | (mass %) | | (mass %) |
| Example | DMSO | — | PG | (Balance) | Na | K | Mg | Ca | B | Al | TMAH |
| 23 | (40) | | (30) | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | DMSO | — | PG | (Balance) | Na | K | Mg | Ca | B | Al | TMAH |
| 24 | (20) | | (5) | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | EDG | — | PG | (Balance) | Na | K | Mg | Ca | B | Al | TMAH |
| 25 | (60) | | (20) | | (1 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | EDG | — | PG | (Balance) | Na | K | Mg | Ca | B | Al | TMAH |
| 26 | (40) | | (20) | | (5 × 10¹ppb) | (5 × 10⁵ppb) | (2 × 10²ppb) | (5 × 10⁻¹ppb) | (2 × 10¹ppb) | (4 × 10−1ppb) | (15) |
| Example | EDG | — | — | (Balance) | Na | K | Mg | Ca | B | Al | TMAH |
| 27 | (20)x | | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | BDG | — | — | (Balance) | Na | K | Mg | Ca | B | Al | TMAH |
| 28 | (60) | | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | BDG | — | — | (Balance) | Na | K | Mg | Ca | B | Al | TMAH |
| 29 | (40) | | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | BDG | — | — | (Balance) | Na | K | Mg | Ca | B | Al | TMAH |
| 30 | (20) | | | | (2 × 10²ppb) | (5 × 10⁵ppb) | (2 × 10²ppb) | (5 × 10⁻¹ppb) | (2 × 10¹ppb) | (4 × 10⁻¹ppb) | (15) |
| Example | DMSO | EDG | PG | (Balance) | — | K | Mg | — | B | — | TMAH |
| 31 | (5) | (35) | (20) | | | (5 × 10⁵ppb) | (2 × 10²ppb) | | (2 × 10¹ppb) | | (10) |
| Example | DMSO | EDG | — | (Balance) | — | K | Mg | — | B | — | TMAH |
| 32 | (30) | (30) | | | | (5 × 10⁵ppb) | (2 × 10²ppb) | | (2 × 10¹ppb) | | (15) |
| Example | DMSO | — | — | (Balance) | — | K | Mg | — | B | — | TMAH |
| 33 | (60) | | | | | (5 × 10⁵ppb) | (2 × 10²ppb) | | (2 × 10¹ppb) | | (15) |

TABLE 4

| | (a) | | | | | | |
|---|---|---|---|---|---|---|---|
| | Water-soluble | | | | (c-1) | | (c-2) |
| | organic solvent | | | (b) | Group 1 metal ion | | Group 2 metal ion |
| | (mass %) | | | Water | (mass %) | | (mass %) |
| Comparative | DMSO | EDG | PG | (Balance) | — | — | — |
| example 1 | (5) | (35) | (20) | | | | |
| Comparative | DMSO | EDG | PG | (Balance) | Na | K | Mg |
| example 2 | (5) | (35) | (20) | | (6 × 10³ppb) | (1 × 10⁸ppb) | (6 × 10³ppb) |
| Comparative | EDG | EDG | PG | (Balance) | Na | K | Mg |
| example 3 | (5) | (35) | (20) | | (3 × 10¹ppb) | (7 × 10³ppb) | (3 × 10⁰ppb) |

| | (c-2) | (c-3) | | (d) |
|---|---|---|---|---|
| | Group 2 metal ion | Group 13 metal ion | | Base |
| | (mass %) | (mass %) | | (mass %) |
| Comparative | — | — | — | TMAH |
| example 1 | | | | (10) |
| Comparative | Ca | B | Al | TMAH |
| example 2 | (4 × 10¹ppb) | (7 × 10²ppb) | (1 × 10¹ppb) | (10) |
| Comparative | Ca | B | Al | TMAH |
| example 3 | (2 × 10⁻³ppb) | (4 × 10⁻¹ppb) | (4 × 10⁻³ppb) | (10) |

### Peelability of Filling

First, sample substrates were prepared in which a film of a filling made of a spin-on-glass material was formed on a laminated substrate having a Cu layer on a Si substrate. The spin-on glass material used was conformed to the description of JP-A-2001-092122. Subsequently, the sample substrates were immersed in the respective processing solutions for lithography of Examples and Comparative examples under the condition of 50° C. for one minute, and then rinsed with pure water. The peeling state of the filling at this time was evaluated by measuring the film thickness of the Cu layer. The results are given in Table 5.

### Suppression of Corrosion of Low-k Material

First, sample substrates were prepared in which a CVD-deposited low dielectric layer (with a dielectric constant from 2.7 to 2.8) was formed on a laminated substrate having a Cu layer on a Si substrate. Subsequently, a trench resist pattern was formed as a mask on each of the low dielectric layers of the sample substrates by lithography. The low dielectric layers used were formed by firing a material of the same kind as a spin-on glass material disclosed in JP-A-2001-092122 at a lower temperature than the crystallization temperature. Then, each of the low dielectric layers was dry-etched to form a trench pattern. Thus, pattern substrates were obtained.

The pattern substrates were immersed in the respective processing solutions for lithography of Examples and Comparative examples under the condition of 50° C. for 10 minutes, and then rinsed with pure water. The corrosion state of each of the low-k materials at this time was evaluated by observation with an SEM (scanning electron microscope, manufactured by Hitachi, Ltd. “S-5200”). The results are given in Table 5.

Regarding the evaluation results in Table 5, “A” and “B” indicate that good peelability or corrosion suppression was observed, and “A” indicates that particularly good peelability or corrosion suppression was observed. On the other hand, “C” indicates that the peelability or corrosion suppression was insufficient.

TABLE 5

| | Peelability of | Suppression of low-k |
|---|---|---|
| | filing material | material corrosion |
| Example 1 | A | A |
| Example 2 | A | A |
| Example 3 | A | A |
| Example 4 | A | A |
| Example 5 | A | A |
| Example 6 | A | A |
| Example 7 | A | A |
| Example 8 | A | A |
| Example 9 | A | A |
| Example 10 | A | A |
| Example 11 | A | A |
| Example 12 | A | A |
| Example 13 | A | A |
| Example 14 | A | A |
| Example 15 | A | A |
| Example 16 | A | A |
| Example 17 | A | A |
| Example 18 | A | A |
| Example 19 | A | A |
| Example 20 | A | A |
| Example 21 | A | A |
| Example 22 | A | A |
| Example 23 | A | A |
| Example 24 | A | A |
| Example 25 | B | A |
| Example 26 | B | A |
| Example 27 | B | A |
| Example 28 | B | A |
| Example 29 | B | A |
| Example 30 | B | A |
| Example 31 | A | A |
| Example 32 | A | A |
| Example 33 | A | A |
| Comparative | C | A |
| example 1 | | |
| Comparative | A | C |
| example 2 | | |
| Comparative | C | A |
| example 3 | | |

From the above, it has been confirmed at least that the processing solution of the present embodiment is excellent in peelability of a filling and suppression of corrosion of a low-k material.

What is claimed is:

1. A processing solution for a semiconductor device, comprising:
(a) a water-soluble organic solvent,
(b) water, and
(c) an ion of a metal element.

2. The processing solution according to claim 1, comprising as the ion of the metal element (c):
at least one selected from the group consisting of (c-1) an ion of a Group 1 metal element, (c-2) an ion of a Group 2 metal element, and (c-3) an ion of a Group 13 metal element.

3. The processing solution according to claim 1, comprising as the ion of the metal element (c):
(c-1) an ion of a Group 1 metal element,
(c-2) an ion of a Group 2 metal element, and
(c-3) an ion of a Group 13 metal element.

4. The processing solution according to claim 2, wherein the ion of the Group 1 metal element (c-1) is a potassium ion and/or a sodium ion.

5. The processing solution according to claim 2, wherein the ion of the Group 2 metal element (c-2) is a magnesium ion and/or a calcium ion.

6. The processing solution according to claim 2, wherein the ion of the Group 13 metal element (c-3) is a boron ion and/or an aluminum ion.

7. The processing solution according to claim 2, wherein the processing solution comprises the ion of the Group 1 metal element (c-1) in an amount from 5×10⁴ ppb by mass to 1×10⁷ ppb by mass with respect to a total mass of the processing solution.

8. The processing solution according to claim 2, wherein the processing solution comprises the ion of the Group 2 metal element (c-2) in an amount from 1×10¹ ppb by mass to 1×10³ ppb by mass with respect to a total mass of the processing solution.

9. The processing solution according to claim 2, wherein the processing solution comprises the ion of the Group 13 metal element (c-3) in an amount from 1×10⁰ ppb by mass to 1×10² ppb by mass with respect to a total mass of the processing solution.

10. The processing solution according to claim 1, further comprising (d) a base other than the component (a), the component (b), and the component (c).

11. The processing solution according to claim 10, wherein the base (d) is a quaternary ammonium hydroxide compound.

12. A method for processing a substrate, comprising:
obtaining a laminated substrate comprising a substrate, a low dielectric layer laminated on the substrate, and a resist pattern laminated on the substrate; and
processing the laminated substrate with the processing solution according to claim 1.

13. The method for processing the substrate according to claim 12, wherein the laminated substrate is obtained using a damascene method.

14. A method for manufacturing a semiconductor substrate, comprising:
obtaining a laminated substrate comprising a substrate, a low dielectric layer laminated on the substrate, and a resist pattern laminated on the substrate; and
processing the laminated substrate with the processing solution according to claim 1.

15. The method for manufacturing the semiconductor substrate according to claim 14, further comprising forming metal wiring by embedding a metal in a pattern space of the resist pattern after the processing.

16. The method for manufacturing the semiconductor substrate according to claim 14,
wherein the laminated substrate is obtained using a damascene method.
